(19) United States
(12) Patent Application Publication
(10) Pub. No.: US 2018/0079763 A1
(43) Pub. Date: Mar. 22, 2018

(54) TRIPHENYLPHOSPHINE OXIDE DERIVATIVE AND ELECTROPHOSPHORESCENT LUMINESCENT DEVICE

(71) Applicant: Wuhan China Star Optoelectronics Technology Co., Ltd., Wuhan (CN)

(72) Inventor: Biao PAN, Wuhan (CN)

(21) Appl. No.: 15/323,511

(22) PCT Filed: Dec. 1, 2016
(86) PCT No.: PCT/CN2016/108187

§ 371 Date: Jan. 3, 2017

(30) Foreign Application Priority Data
Sep. 21, 2016 (CN) 201610846954.3

(51) Int. Cl. C07F 9/6506; H01L 51/00; H01L 51/50; C09K 11/06

(52) U.S. Cl. CPC C07F 9/65068; H01L 51/0072; C09K 2211/1096; C09K 11/06; H01L 51/5072

(57) ABSTRACT

A triphenylphosphine oxide derivative is described, which is applied to a phosphorescence host and an electron transport material. R in a structural formula of the triphenylphosphine oxide derivative is H or a substituent group with an electron transporting property. An electrophosphorescent luminescent device is further described. An electron mobility and a luminous efficiency of a light emitting device are improved and a roll-off efficiency of the light emitting device is reduced by all using H or substituent groups with electron transporting properties as R groups of the triphenylphosphine oxide derivative.

### FIELD OF THE INVENTION

The present invention relates to a light emitting material field, and more particularly to a triphenylphosphine oxide derivative and an electrophosphorescent luminescent device.

### BACKGROUND OF THE INVENTION

In 1987, Prof. Deng Qingyun and Vanslyke fabricated a double-layer organic electroluminescent device by using an ultra-thin film technology which utilizes a transparent conductive film as an anode electrode, AlQ₃ as a light emitting layer, triarylamine as a hole transport layer, and a Mg/Ag annoy as a cathode electrode.

In 1990, Burroughes et al. found an OLED using a conjugated molecule as a light emitting layer, thereby setting off a boom worldwide.

Due to the influence of spin restriction, in daily life we see mostly fluorescence phenomenon. The initial OLED technology research focused on the direction of the fluorescent device. However, according to the spin quantum statistical theory, the maximum internal quantum efficiency of the fluorescent electroluminescent device is only 25%, while that of the phosphorescent electroluminescent device can reach 100%. Therefore, in 1999, Forrest and Thompson et al. doped the green phosphorescent material Ir(ppy)₃ at a concentration of 6 wt % in the host material of 4,4′-N, N′-dicarbazole-biphenyl(CBP). A green light OLED was obtained and has a maximum external quantum efficiency (EQE) reaching 8%. After breaking the theoretical limits of electroluminescence devices, phosphorescent luminescent materials have attracted great attention. Since then, the electro-phosphorescent materials and phosphorescent devices have been the focus of OLED research.

For organic semiconductor materials, the electron transport rate is much slower than the hole transport rate; therefore, the efficiency of the light emitting device is relatively low and the roll-off efficiency of the light emitting device is greatly reduced due to the lower electron mobility.

As a result, it is necessary to provide a triphenylphosphine oxide derivative and an electrophosphorescent luminescent device to solve the problems existing in the conventional technologies.

### SUMMARY OF THE INVENTION

An embodiment of the present invention provides a triphenylphosphine oxide derivative and an electrophosphorescent luminescent device to enable a corresponding light emitting device having a relatively high luminous efficiency and a relatively low roll-off efficiency, so as to solve the technical problems induced by the efficiency of the light emitting device being relatively low and the roll-off efficiency of the light emitting device being greatly reduced due to the lower electron mobility.

An embodiment of the present invention provides a triphenylphosphine oxide derivative, applied to a phosphorescence host and an electron transport material, wherein the triphenylphosphine oxide has a structural formula shown as follows:

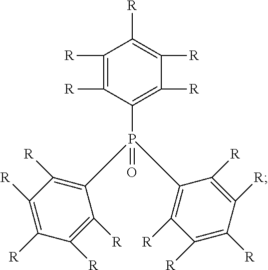

wherein each of the R in the structural formula is H or a substituent group with an electron transporting property;
wherein the substituent group with the electron transporting property comprises:

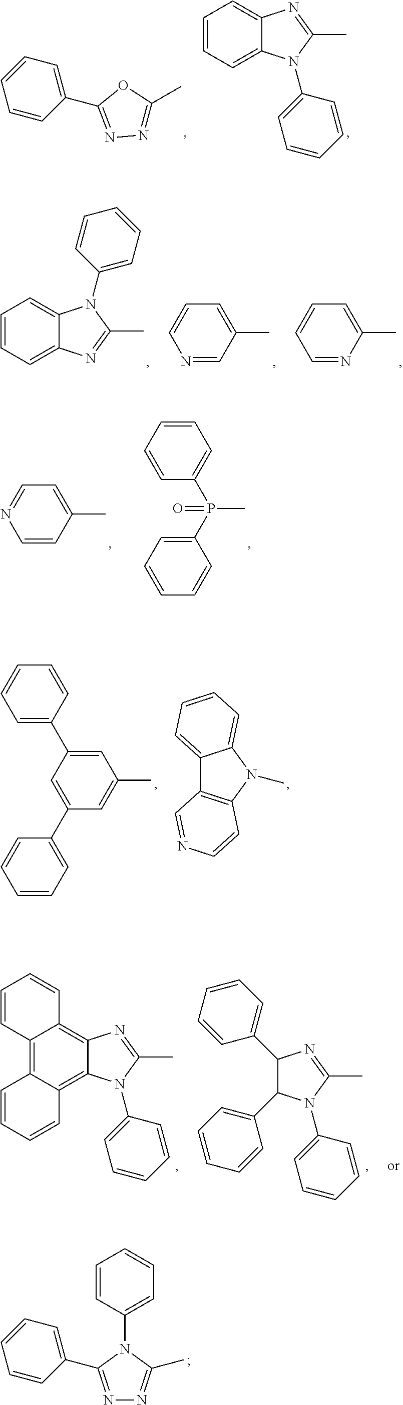

wherein all of the R are substituent groups with an identical structure; or all of the R comprise at least two types of substituent groups with different structures.

An embodiment of the present invention provides a triphenylphosphine oxide derivative, applied to a phosphorescence host and an electron transport material, wherein the triphenylphosphine oxide has a structural formula shown as follows:

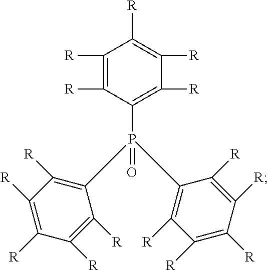

wherein each of the R in the structural formula is H or a substituent group with an electron transporting property.

In the triphenylphosphine oxide derivative described by the present invention, the substituent group with the electron transporting property comprises:

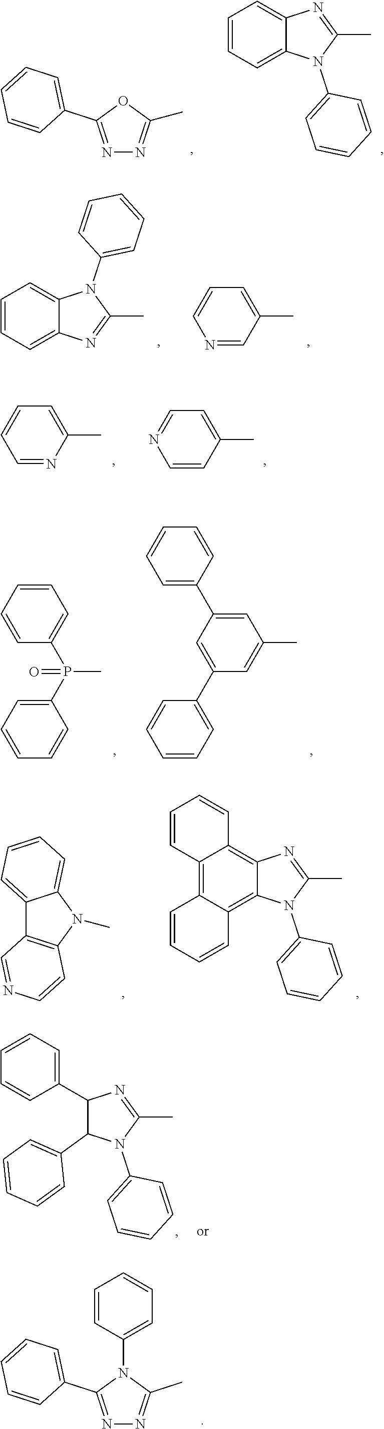

An embodiment of the present invention further provides an electrophosphorescent luminescent device, comprising a substrate, a transparent anode electrode, a hole injection layer, a hole transport layer, an exciton blocking layer, a light emitting layer, an electron transport layer, an electron injection layer, and a cathode electrode disposed in sequence, wherein the light emitting layer at least partially comprises a triphenylphosphine oxide derivative, and the triphenylphosphine oxide derivative has a structural formula shown as follows:

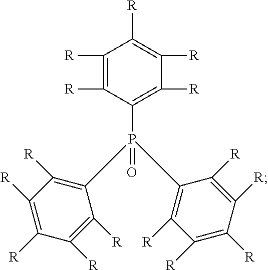

wherein each of the R in the structural formula is H or a substituent group with an electron transporting property.

In the electrophosphorescent luminescent device described by the present invention, the substituent group with the electron transporting property comprises:

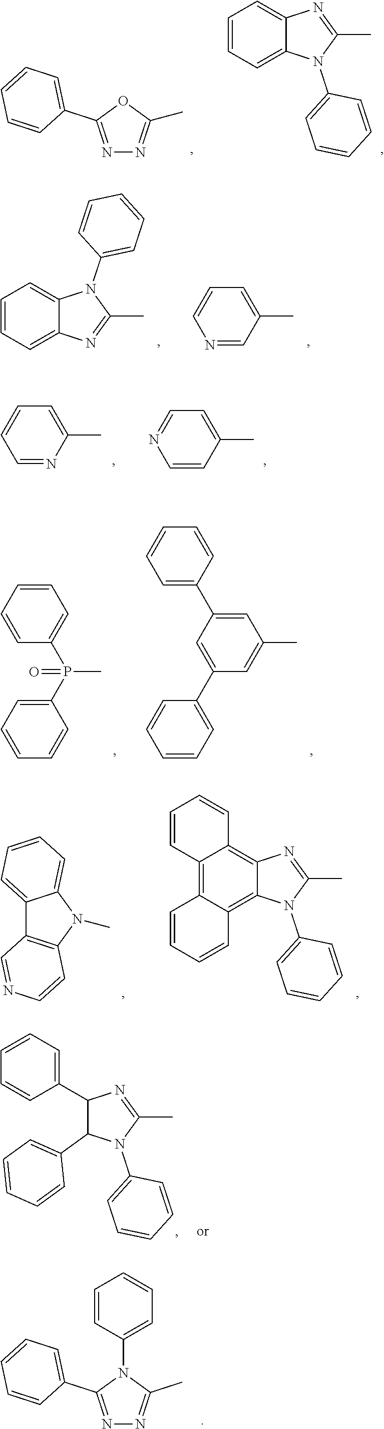

In the electrophosphorescent luminescent device described by the present invention, all of the R are substituent groups with an identical structure; or all of the R comprise at least two types of substituent groups with different structures.

In comparison with a conventional triphenylphosphine oxide derivative and an electrophosphorescent luminescent device, the triphenylphosphine oxide derivative and the electrophosphorescent luminescent device of the present invention improves electron mobility and a luminous efficiency of a light emitting device and reduces a roll-off efficiency of the light emitting device by using H or substituent groups with electron transporting properties entirely as R groups of the triphenylphosphine oxide derivative, so as to solve the technical problems induced by the efficiency of the light emitting device being relatively low and the roll-off efficiency of the light emitting device being greatly reduced due to the lower electron mobility of the conventional light emitting device.

To make the above description of the present invention more clearly comprehensible, it is described in detail below in examples of preferred embodiments with the accompanying drawings.

### DESCRIPTION OF THE DRAWINGS

FIG. 1 is a structural schematic diagram of a preferred embodiment of an electrophosphorescent luminescent device of the present invention;

FIGS. 2a to 2d are structural energy level schematic diagrams of preferred embodiments of electrophosphorescent luminescent devices of the present invention;

FIG. 3 is a curve diagram of brightness versus voltage current density of a preferred embodiment of an electrophosphorescent luminescent device of the present invention;

FIG. 4 is a curve diagram of power efficiency versus current efficiency versus brightness of a preferred embodiment of an electrophosphorescent luminescent device of the present invention;

FIG. 5 is a curve diagram of electroluminescent intensity versus wavelength of a preferred embodiment of an electrophosphorescent luminescent device of the present invention; and

FIG. 6 is a curve diagram of electric field strength versus electron field strength of a preferred embodiment of an electrophosphorescent luminescent device of the present invention.

### DETAILED DESCRIPTION OF THE PREFERRED EMBODIMENTS

The following description of the embodiments with reference to the appended drawings is used for illustrating specific embodiments which may be used for carrying out the present invention. The directional terms described by the present invention, such as “upper”, “lower”, “front”, “back”, “left”, “right”, “inner”, “outer”, “side”, etc., are only directions by referring to the accompanying drawings. Thus, the used directional terms are used to describe and understand the present invention, but the present invention is not limited thereto.

In the figures, elements with similar structures are indicated by the same numbers.

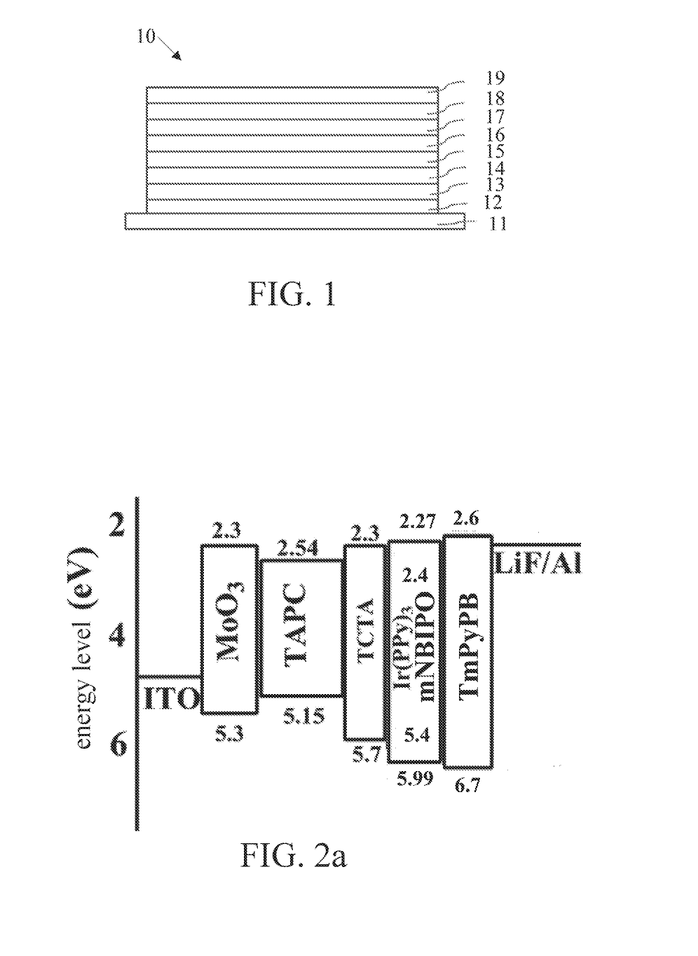

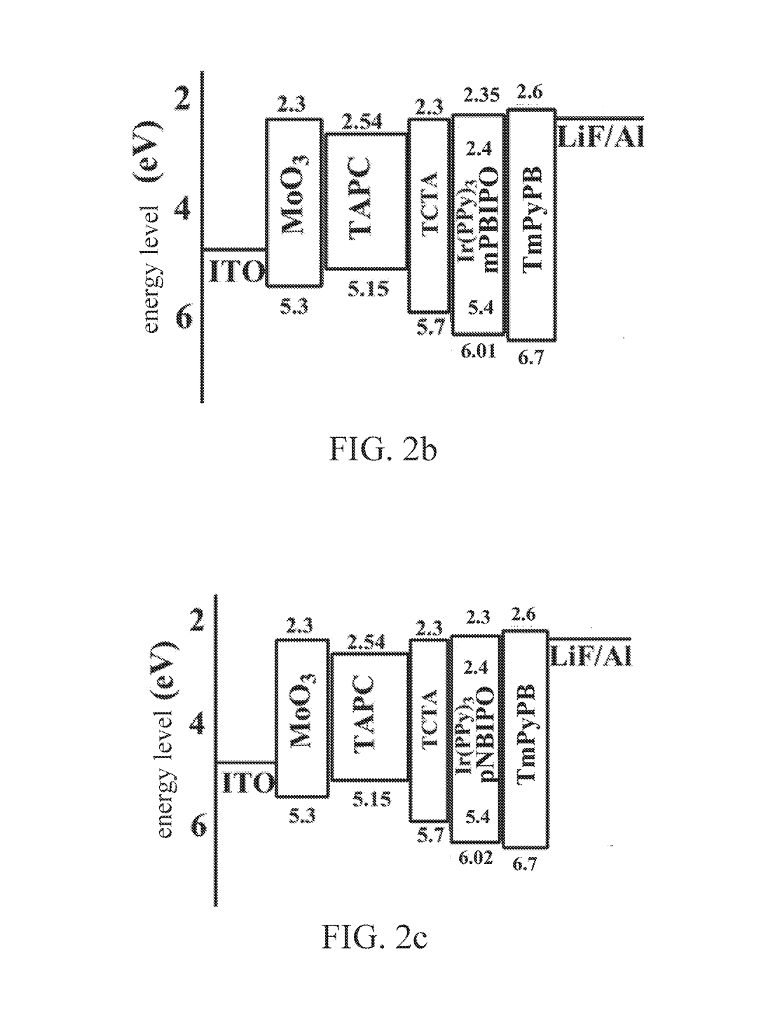

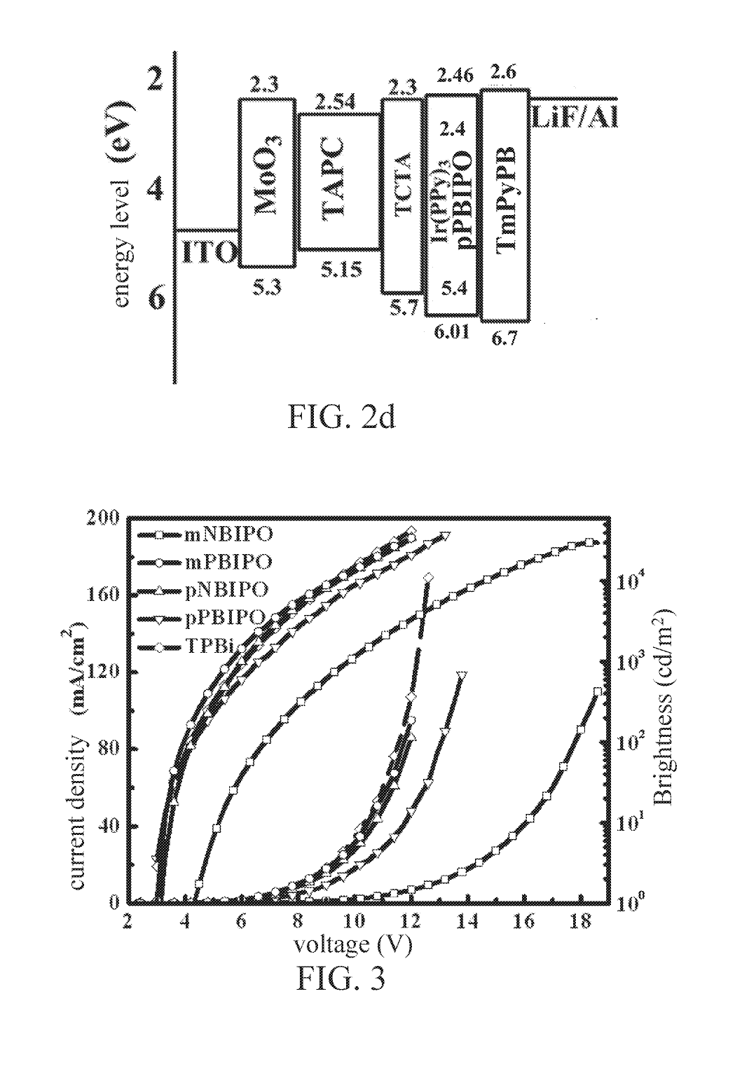

Please refer to FIG. 1, FIG. 2a, FIG. 2b, FIG. 2c, and FIG. 2d. FIG. 1 is a structural schematic diagram of a preferred embodiment of an electrophosphorescent luminescent device of the present invention; and FIGS. 2a to 2d are structural energy level schematic diagrams of preferred embodiments of electrophosphorescent luminescent devices of the present invention. An electrophosphorescent luminescent device 10 of the present preferred embodiment comprises a substrate 11, a transparent anode electrode 12, a hole injection layer 13, a hole transport layer 14, an exciton blocking layer 15, a light emitting layer 16, an electron transport layer 17, an electron injection layer 18, and a cathode electrode 19 disposed in sequence, wherein the light emitting layer 16 at least partially comprises a triphenylphosphine oxide derivative.

The triphenylphosphine oxide derivative has a structural formula shown as follows:

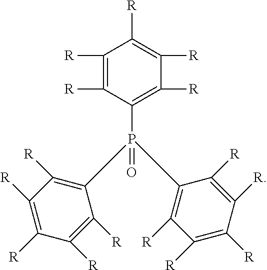

In some embodiments, each of the R in the structural formula is H or a substituent group with an electron transporting property.

The substituent group with the electron transporting property comprises but is not limited to:

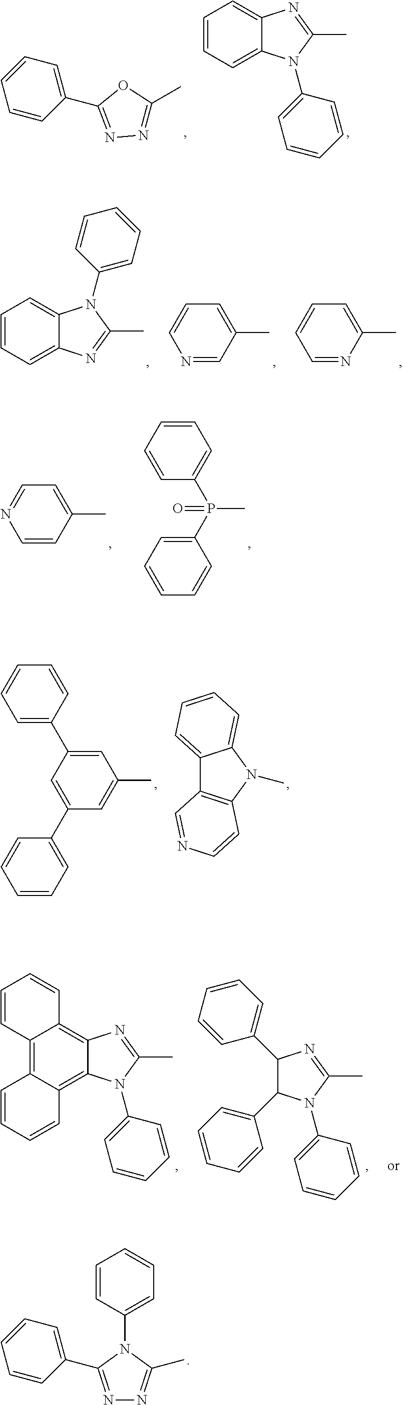

In some embodiments, all of the R are substituent groups with an identical structure; or all of R comprise at least two types of substituent groups with different structures. All of the R in the same benzene ring are substituent groups with identical structures; or all of the R in the same benzene ring comprise at least two types of substituent groups with different structures.

The transparent anode electrode 12 of the electrophosphorescent luminescent device 10 of the preferred embodiment is made of ITO (Indium Tin Oxides; Indium Tin Oxide); the hole injection layer 13 is made of MoO₃ (Molybdenum trioxide); the hole transport layer 14 is made of TAPC; the exciton blocking layer 15 is made of TCTA; a guest material of the light emitting layer 16 is made of a phosphorescent material Ir(ppy)₃; a main material of the light emitting layer 16 is made of a triphenylphosphine oxide derivative; the electron transport layer 17 is made of TmPyPB; the electron injection layer 18 is made of LiF (Lithium fluoride); and the cathode electrode 19 is made of Al.

In some embodiments, the triphenylphosphine oxide derivative can be pNBIPO, pPBIPO, mNBIPO, or mPBIPO.

In some embodiments, a structural formula of the pNBIPO is shown as follows:

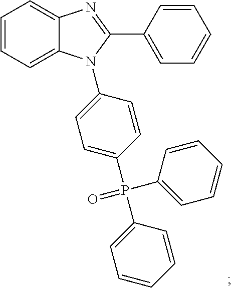 [SMILES: O=P(c1ccccc1)(c1ccccc1)c1ccc(-n2c(-c3ccccc3)nc3ccccc32)cc1]

a structural formula of the pPBIPO is shown as follows:

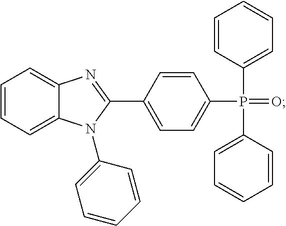 [SMILES: O=P(c1ccccc1)(c1ccccc1)c1ccc(-c2nc3ccccc3n2-c2ccccc2)cc1]

a structural formula of the mNBIPO is shown as follows:

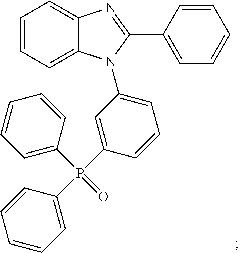 [SMILES: O=P(c1ccccc1)(c1ccccc1)c1cccc(-n2c(-c3ccccc3)nc3ccccc32)c1]

and

a structural formula of the mPBIPO is shown as follows:

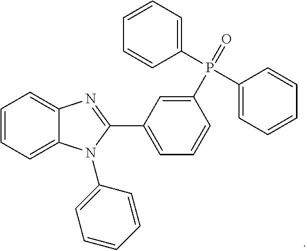 [SMILES: O=P(c1ccccc1)(c1ccccc1)c1cccc(-c2nc3ccccc3n2-c2ccccc2)c1]

A structural formula of the Ir(ppy)₃ is shown as follows:

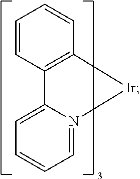

a structural formula of the TmPyPB is shown as follows:

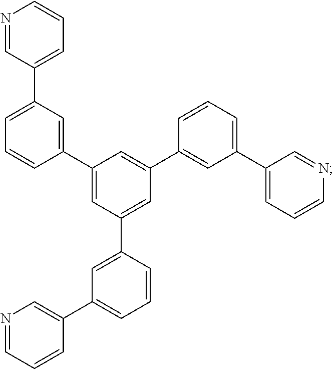 [SMILES: c1cncc(-c2cccc(-c3cc(-c4cccc(-c5cccnc5)c4)cc(-c4cccc(-c5cccnc5)c4)c3)c2)c1]

a structural formula of the TAPC is shown as follows:

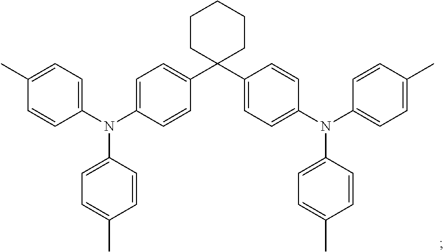

and

a structural formula of the TCTA is shown as follows:

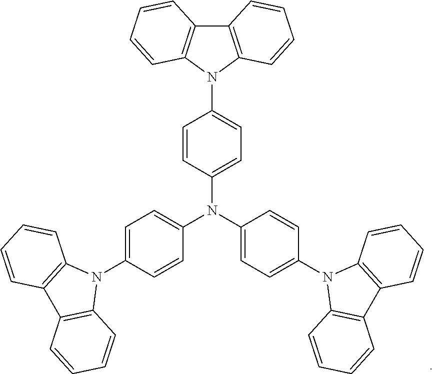 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1]

In the electrophosphorescent luminescent device of the present preferred embodiment, a thickness of the hole injection layer 13 is ranged from 8 nm to 12 nm, preferably 10 nm; a thickness of the hole transport layer 14 is ranged from 60 nm to 80 nm, preferably 40 nm; a thickness of the exciton blocking layer 15 is ranged from 4 nm to 6 nm, preferably 5 nm; a thickness of the light emitting layer 16 is ranged from 15 nm to 25 nm, preferably 20 nm; a thickness of the electron transport layer 17 is ranged from 35 nm to 45 nm, preferably 40 nm; and a thickness of the electron injection layer 18 is ranged from 0.8 nm to 1.2 nm, preferably 1 nm. A thickness of the cathode electrode 19 is ranged from 140 nm to 160 nm, preferably 150 nm.

Please refer to FIG. 2a to FIG. 2d, which are four types of structural energy levels of the electrophosphorescent luminescent devices with different light emitting layers.

When an R of the triphenylphosphine oxide derivative is

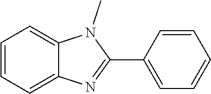 [SMILES: Cn1c(-c2ccccc2)nc2ccccc21]

and all of the remaining R are H, the triphenylphosphine oxide derivative is 4-(1-methylbenzimidazolyl)-triphenylphosphine oxide, i.e. pNBIPO.

When an R of the triphenylphosphine oxide derivative is

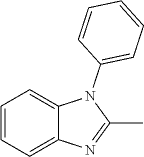 [SMILES: Cc1nc2ccccc2n1-c1ccccc1]

and all of the remaining R are H, the triphenylphosphine oxide derivative is 4-(2-methylbenzimidazolyl)-triphenylphosphine oxide, i.e. pPBIPO.

When an R of the triphenylphosphine oxide derivative is

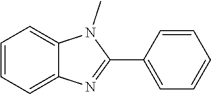 [SMILES: Cn1c(-c2ccccc2)nc2ccccc21]

and all of the remaining R are H, the triphenylphosphine oxide derivative is 3-(1-methylbenzimidazolyl)-triphenylphosphine oxide, i.e. mNBIPO.

When an R of the triphenylphosphine oxide derivative is

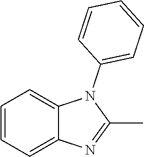 [SMILES: Cc1nc2ccccc2n1-c1ccccc1]

and all of the remaining R are H, the triphenylphosphine oxide derivative is 3-(2-methylbenzimidazolyl)-triphenylphosphine oxide, i.e. mPBIPO.

In the present preferred embodiment, the pNBIPO can be synthesized by the following method.

2-Phenyl-4-N-p-bromophenylbenzimidazole (1.0 mmol) is dissolved in THF (tetrahydrofuran) (50 ml) and cooled to −78° C., and then butyllithium (1.1 mmol) is added and reacted for 1 hour. Then, diphenylphosphonium chloride (1.2 mmol) is further added and reacts by heating to room temperature for 12 hours. Then, methanol is added for quenching reaction, and 30% H₂O₂ aqueous (5 ml) is added for oxidation to obtain 4-(1-methylbenzimidazolyl)-triphenylphosphoric oxide (pNBIPO). Yield: 70%.

A process of fabricating an electrophosphorescent luminescent device 10 by using pNBIPO as a material of the light emitting material comprises steps of: washing ITO in cleaning agents and deionized water by ultrasound wave for 30 minutes; then, vacuum drying at 105° C. for 2 hours; further, placing ITO into an ionization reactor to perform a CFₓ plasma treatment for 1 minute and transporting into a vacuum chamber to fabricating an organic film and a metal electrode. The pNBIPO is used as a main material of the light emitting layer by a vacuum electroplating method. A structure of the electrophosphorescent luminescent device is:

ITO/MoO₃(10 nm)/TAPC(70 nm)/TCTA(5 nm)/pNBIPO-Ir(ppy)₃(20 nm)/TmPyPB(40 nm)/LiF(1 nm)/Al.

In the present preferred embodiment, the pPBIPO can be synthesized by the following method.

N-Phenyl-4-p-bromophenylbenzimidazole (1.0 mmol) is dissolved in THF (tetrahydrofuran) (50 ml) and cooled to −78° C., and then butyllithium (1.1 mmol) is added and reacted for 1 hour. Then, diphenylphosphonium chloride (1.2 mmol) is further added and reacts by heating to room temperature for 12 hours. Then, methanol is added for quenching reaction, and 30% H₂O₂ aqueous (5 ml) is added for oxidation to obtain 4-(2-methylbenzimidazolyl)-triphenylphosphoric oxide (pPBIPO). Yield: 70%.

A process of fabricating an electrophosphorescent luminescent device 10 by using pPBIPO as a material of the light emitting material comprises steps of: washing ITO in cleaning agents and deionized water by ultrasound wave for 30 minutes; then, vacuum drying at 105° C. for 2 hours; further, placing ITO into an ionization reactor to perform a CFₓ plasma treatment for 1 minute and transporting into a vacuum chamber to fabricating an organic film and a metal electrode. The pPBIPO is used as a main material of the light emitting layer by a vacuum electroplating method. A structure of the electrophosphorescent luminescent device is:

ITO/MoO₃(10 nm)/TAPC(70 nm)/TCTA(5 nm)/pPBIPO-Ir(ppy)₃(20 nm)/TmPyPB(40 nm)/LiF(1 nm)/Al.

In the present preferred embodiment, the mNBIPO can be synthesized by the following method.

2-phenyl-3-m-bromophenylbenzimidazole (1.0 mmol) is dissolved in THF (tetrahydrofuran) (50 ml) and cooled to −78° C., and then butyllithium (1.1 mmol) is added and reacted for 1 hour. Then, diphenylphosphonium chloride (1.2 mmol) is further added and reacts by heating to room temperature for 12 hours. Then, methanol is added for quenching reaction, and 30% aqueous H₂O₂ (5 ml) is added for oxidation to obtain 3-(2-methylbenzimidazolyl)-triphenylphosphoric oxide (mNBIPO). Yield: 70%.

A process of fabricating an electrophosphorescent luminescent device 10 by using mNBIPO as a material of the light emitting material comprises steps of: washing ITO in cleaning agents and deionized water by ultrasound wave for 30 minutes; then, vacuum drying at 105° C. for 2 hours; further, placing ITO into an ionization reactor to perform a CFₓ plasma treatment for 1 minute and transporting into a vacuum chamber to fabricating an organic film and a metal electrode. The mNBIPO is used as a main material of the light emitting layer by a vacuum electroplating method. A structure of the electrophosphorescent luminescent device is:

ITO/MoO₃(10 nm)/TAPC(70 nm)/TCTA(5 nm)/mPBIPO-Ir(ppy)₃(20 nm)/TmPyPB(40 nm)/LiF(1 nm)/Al.

In the present preferred embodiment, the mPBIPO can be synthesized by the following method.

N-phenyl-3-m-bromophenylbenzimidazole (1.0 mmol) is dissolved in THF (tetrahydrofuran) (50 ml) and cooled to −78° C., and then butyllithium (1.1 mmol) is added and reacted for 1 hour. Then, diphenylphosphonium chloride (1.2 mmol) is further added and reacts by heating to room temperature for 12 hours. Then, methanol is added for quenching reaction, and 30% aqueous H₂O_{2 (}5 ml) is added for oxidation to obtain 3-(2-methylbenzimidazolyl)-triphenylphosphoric oxide (mPBIPO). Yield: 70%.

A process of fabricating an electrophosphorescent luminescent device 10 by using mPBIPO as a material of the light emitting material comprises steps of: washing ITO in cleaning agents and deionized water by ultrasound wave for 30 minutes; then, vacuum drying at 105° C. for 2 hours; further, placing ITO into an ionization reactor to perform a CFₓ plasma treatment for 1 minute and transporting into a vacuum chamber to fabricating an organic film and a metal electrode. The mPBIPO is used as a main material of the light emitting layer by a vacuum electroplating method. A structure of the electrophosphorescent luminescent device is:

ITO/MoO₃(10 nm)/TAPC(70 nm)/TCTA(5 nm)/mPBIPO-Ir(ppy)₃(20 nm)/TmPyPB(40 nm)/LiF(1 nm)/Al.

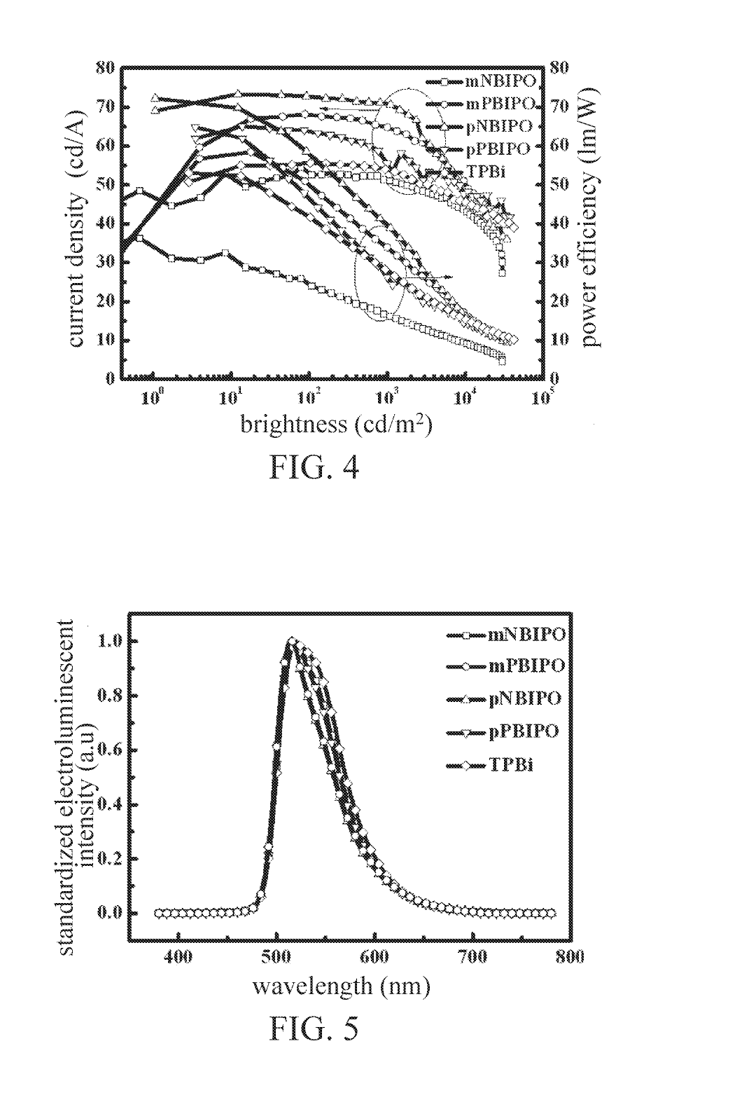

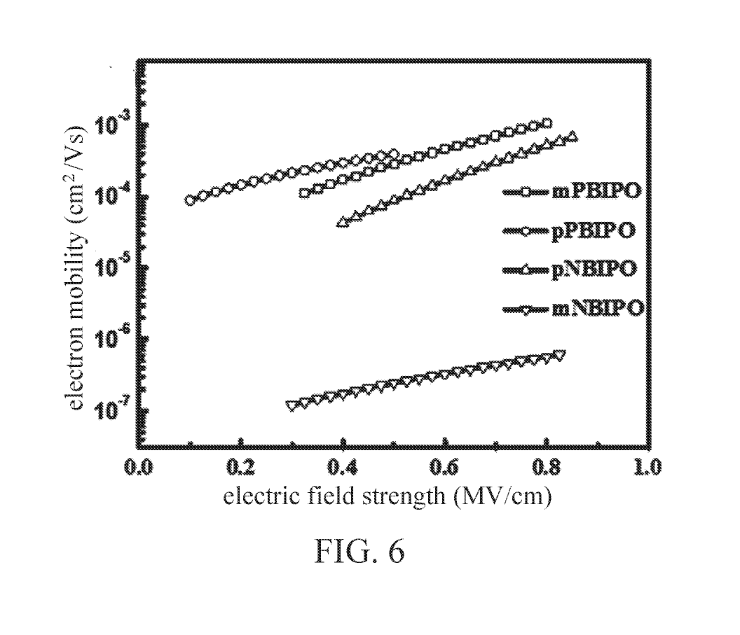

Please refer FIG. 3 to FIG. 6. FIG. 3 is a curve diagram of brightness versus voltage current density of a preferred embodiment of an electrophosphorescent luminescent device of the present invention; FIG. 4 is a curve diagram of power efficiency versus current efficiency versus brightness of a preferred embodiment of an electrophosphorescent luminescent device of the present invention; FIG. 5 is a curve diagram of electroluminescent intensity versus wavelength of a preferred embodiment of an electrophosphorescent luminescent device of the present invention; and FIG. 6 is a curve diagram of electric field strength versus electron field strength of a preferred embodiment of an electrophosphorescent luminescent device of the present invention.

As can be seen from the figures, mNBIPO, mPBIPO, pNBIPO, and pPBIPO show good efficiencies as electron transport materials in evaporation devices. Their η_{CE,max} respectively achieved 54.5, 73.4, 68.2, and 65.1 cd/A; their η_{PE,max} respectively achieved 32.6, 72.2, 58.4, and 64.8 Im/W; and EQEₘₐₓ respectively achieved 14.9%, 20.8%, 19.3%, and 17.9%. However, in comparison with a common benzimidazole electron transport material TPBi as an electron transport material, device efficiencies corresponding to the electrophosphorescent luminescent device are respectively 55.6 cd/A, 53.1 Im/W, and 15.0%. From the view of the luminous efficiency, a luminous efficiency of the electrophosphorescent luminescent device corresponding to mNBIPO is slightly below that of the electrophosphorescent luminescent device corresponding to TPBi. This is because an electron mobility of mNBIPO is lower than that of TPBi. Each of the luminous efficiencies of other electrophosphorescent luminescent devices are all better than that of the electrophosphorescent luminescent device corresponding to TPBi. This indicates that the diphenylphosphine oxide substituted benzimidazoles compounds are more suitable for the electron transporting materials in green phosphorescent devices for small molecule vapor deposition.

The triphenylphosphine oxide derivative provided by the present invention has relatively high electron mobility and can realize transmission rate matching between electrons and holes. Further, the electrophosphorescent luminescent device using the triphenylphosphine oxide derivative as the light emitting layer has an excellent performance, and the current efficiency, the power efficiency and the external quantum efficiency all achieve the highest level of those in the conventional green phosphorescent devices. Simultaneously, the electrophosphorescent luminescent device using the triphenylphosphine oxide derivative as the light emitting layer has a better stability in relatively high voltage range, so as to decrease the energy barrier between the electron transport layer and the light emitting layer and avoid interfacial charge accumulation and exciton quenching, which are beneficial to the improvement of device lifetime and has wide application prospect in full color display field.

The triphenylphosphine oxide derivative and the electrophosphorescent luminescent device of the present invention improves an electron mobility and a luminous efficiency of a light emitting device and reduces a roll-off efficiency of the light emitting device by all using H or substituent groups with electron transporting properties as R groups of the triphenylphosphine oxide derivative, so as to solve the technical problems induced by the efficiency of the light emitting device being relatively low and the roll-off efficiency of the light emitting device being greatly reduced due to the lower electron mobility of the conventional light emitting device.

As described above, although the present invention has been described in preferred embodiments, they are not intended to limit the invention. One of ordinary skill in the art, without departing from the spirit and scope of the invention within, can make various modifications and variations, so the range of the scope of the invention is defined by the claims.

What is claimed is:

1. A triphenylphosphine oxide derivative, applied to a phosphorescence host and an electron transport material, wherein the triphenylphosphine oxide has a structural formula shown as follows: 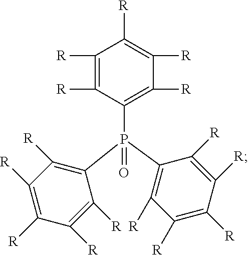
wherein each of the R in the structural formula is H or a substituent group with an electron transporting property;
wherein the substituent group with the electron transporting property comprises: 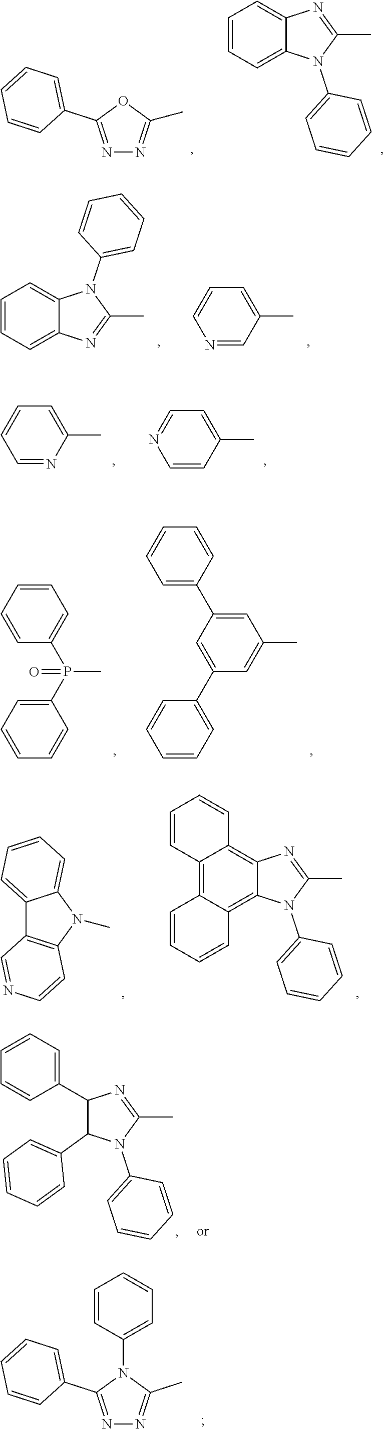
wherein all of the R are substituent groups with an identical structure; or all of the R comprise at least two types of substituent groups with different structures.

2. The triphenylphosphine oxide derivative according to claim 1, wherein all of the R in the same benzene ring are substituent groups with identical structures; or all of the R in the same benzene ring comprise at least two types of substituent groups with different structures.

3. A triphenylphosphine oxide derivative, applied to a phosphorescence host and an electron transport material, wherein the triphenylphosphine oxide has a structural formula shown as follows: 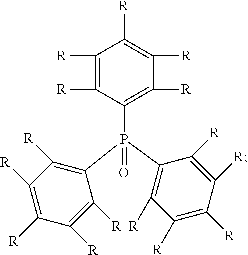
wherein each of the R in the structural formula is H or a substituent group with an electron transporting property.

4. The triphenylphosphine oxide derivative according to claim 3, wherein the substituent group with the electron transporting property comprises:

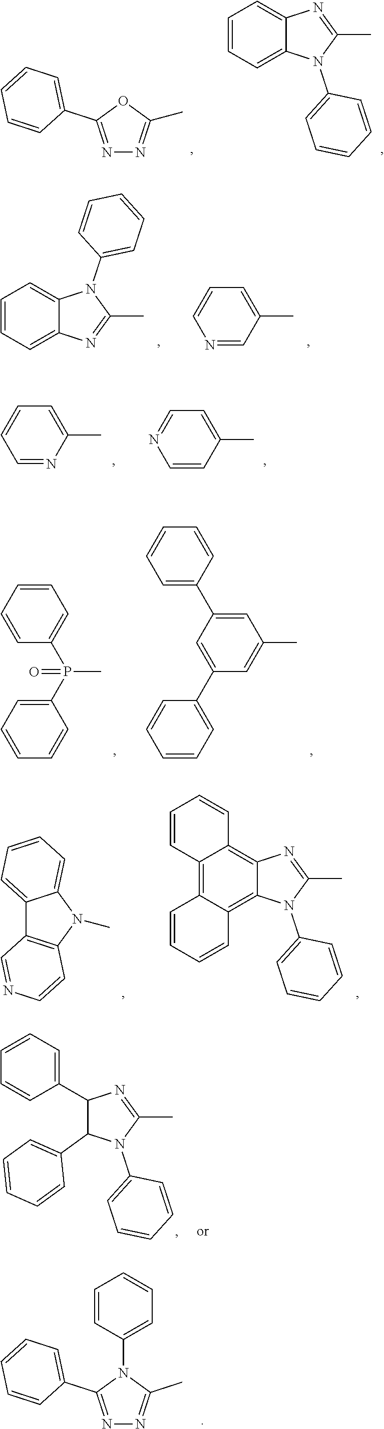

5. The triphenylphosphine oxide derivative according to claim 3, wherein all of the R are substituent groups with an identical structure; or all of the R comprise at least two types of substituent groups with different structures.

6. The triphenylphosphine oxide derivative according to claim 5, wherein all of the R in the same benzene ring are substituent groups with identical structures; or all of the R in the same benzene ring comprise at least two types of substituent groups with different structures.

7. An electrophosphorescent luminescent device, comprising a substrate, a transparent anode electrode, a hole injection layer, a hole transport layer, an exciton blocking layer, a light emitting layer, an electron transport layer, an electron injection layer, and a cathode electrode disposed in sequence, wherein the light emitting layer at least partially comprises a triphenylphosphine oxide derivative, and the triphenylphosphine oxide derivative has a structural formula shown as follows: 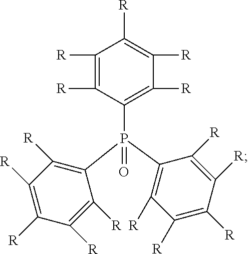
wherein each of the R in the structural formula is H or a substituent group with an electron transporting property.

8. The electrophosphorescent luminescent device according to claim 7, wherein the substituent group with the electron transporting property comprises:

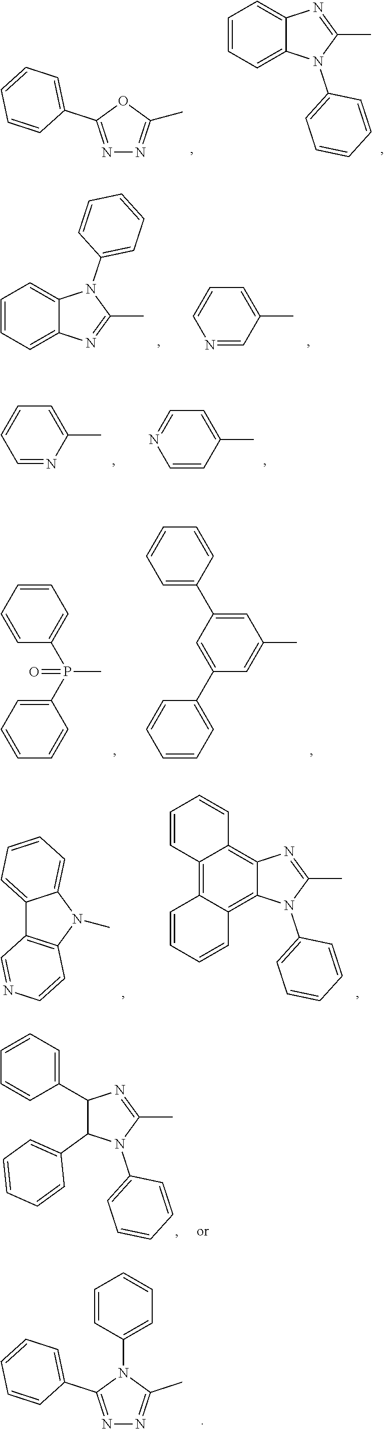

9. The electrophosphorescent luminescent device according to claim 7, wherein all of the R are substituent groups with an identical structure; or all of the R comprise at least two types of substituent groups with different structures.

10. The electrophosphorescent luminescent device according to claim 9, wherein all of the R in the same benzene ring are substituent groups with identical structures; or all of the R in the same benzene ring comprise at least two types of substituent groups with different structures.

11. The electrophosphorescent luminescent device according to claim 7, wherein the transparent anode electrode is ITO; the hole injection layer is MoO₃; the hole transport layer is TAPC; the exciton blocking layer is TCTA;
the light emitting layer is the triphenylphosphine oxide derivative doped with Ir(ppy)₃; the electron transport layer is TmPyPB; the electron injection layer is LiF; and the cathode electrode is Al.

12. The electrophosphorescent luminescent device according to claim 11, wherein the triphenylphosphine oxide derivative is pNBIPO, pPBIPO, mNBIPO, or mPBIPO.

13. The electrophosphorescent luminescent device according to claim 11, wherein a thickness of the hole injection layer is ranged from 8 nm to 12 nm; a thickness of the hole transport layer is ranged from 60 nm to 80 nm; a thickness of the exciton blocking layer is ranged from 4 nm to 6 nm; a thickness of the light emitting layer is ranged from 15 nm to 25 nm; a thickness of the electron transport layer is ranged from 35 nm to 45 nm; and a thickness of the electron injection layer is ranged from 0.8 nm to 1.2 nm.

14. The electrophosphorescent luminescent device according to claim 11, wherein a structural formula of the TAPC is shown as follows: 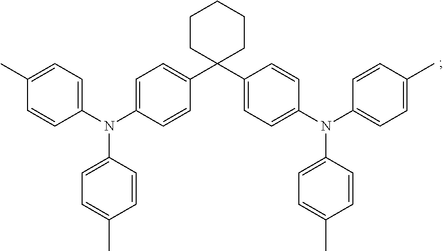
wherein a structural formula of the TCTA is shown as follows: 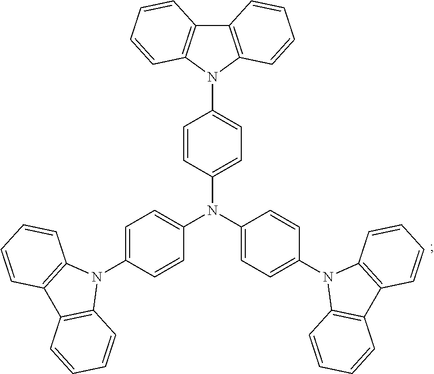 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1]
wherein a structural formula of the Ir(ppy)₃ is shown as follows: 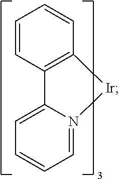
and
wherein a structural formula of the TmPyPB is shown as follows:

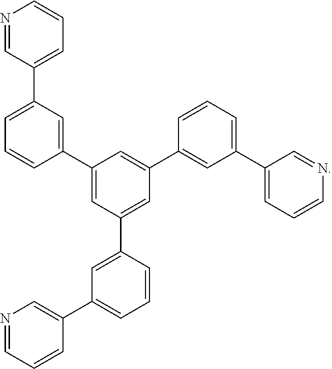 [SMILES: c1cncc(-c2cccc(-c3cc(-c4cccc(-c5cccnc5)c4)cc(-c4cccc(-c5cccnc5)c4)c3)c2)c1]

15. The electrophosphorescent luminescent device according to claim 12, wherein a structural formula of the pNBIPO is shown as follows: 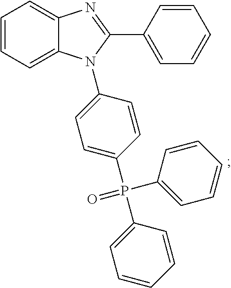 [SMILES: O=P(c1ccccc1)(c1ccccc1)c1ccc(-n2c(-c3ccccc3)nc3ccccc32)cc1]
wherein a structural formula of the pPBIPO is shown as follows: 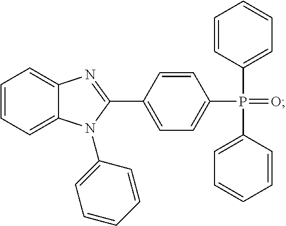 [SMILES: O=P(c1ccccc1)(c1ccccc1)c1ccc(-c2nc3ccccc3n2-c2ccccc2)cc1]
wherein a structural formula of the mNBIPO is shown as follows: 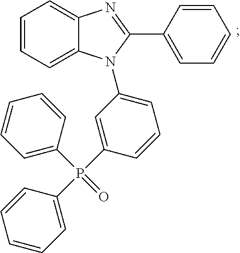 [SMILES: O=P(c1ccccc1)(c1ccccc1)c1cccc(-n2c(-c3ccccc3)nc3ccccc32)c1]
and
wherein a structural formula of the mPBIPO is shown as follows: 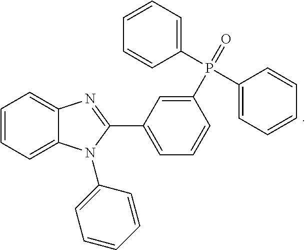 [SMILES: O=P(c1ccccc1)(c1ccccc1)c1cccc(-c2nc3ccccc3n2-c2ccccc2)c1]
